(19) United States
(12) Patent Application Publication
(10) Pub. No.: US 2020/0013621 A1
(43) Pub. Date: Jan. 9, 2020

(54) METHODS FOR INCREASING BEAM CURRENT IN ION IMPLANTATION

(71) Applicants: Aaron Reinicker, Buffalo, NY (US); Ashwini K Sinha, East Amherst, NY (US)

(72) Inventors: Aaron Reinicker, Buffalo, NY (US); Ashwini K Sinha, East Amherst, NY (US)

(21) Appl. No.: 16/519,180

(22) Filed: Jul. 23, 2019

Related U.S. Application Data
(63) Continuation of application No. 15/483,522, filed on Apr. 10, 2017.
(60) Provisional application No. 62/321,069, filed on Apr. 11, 2016.

(51) Int. Cl. H01L 21/265; C23C 14/48; H01J 37/08; H01J 37/317

(52) U.S. Cl. CPC H01L 21/265; C23C 14/48; H01J 2237/31701; H01J 37/3171; H01J 2237/006; H01J 37/08

(57) ABSTRACT

The present invention relates to an improved method for increasing a beam current as part of an ion implantation process. The method comprises introducing a dopant source and an assistant species into an ion implanter. A plasma of ions is formed and then extracted from the ion implanter. Non-carbon target ionic species are separated to produce a beam current that is higher in comparison to that generated solely from the dopant source.

### RELATED APPLICATIONS

The present application is a continuation of U.S. application Ser. No. 15/483,522, filed Apr. 10, 2017, which claims priority to U.S. Application Ser. No. 62/321,069, filed Apr. 11, 2016, each of which is hereby incorporated by reference in its entirety for all purposes.

### FIELD OF THE INVENTION

The present invention relates to methods for increasing a beam current of a non-carbon target ionic species in ion implantation.

### BACKGROUND OF THE INVENTION

Ion implantation is utilized in the fabrication of semiconductor based devices such as Light Emitting Diodes (LED), solar cells, and Metal Oxide Semiconductor Field Effect Transistors (MOSFET). Ion implantation is used to introduce dopants to alter the electronic or physical properties of semiconductors.

In a traditional ion implantation system, a gaseous species often referred to as the dopant source is introduced in to the arc chamber of an ion source. The ion source chamber comprises a cathode which is heated to its thermionic generation temperature to generate electrons. Electrons accelerate towards the arc chamber wall and collide with the dopant source gas molecule present in the arc chamber to generate a plasma. The plasma comprises dissociated ions, radicals, and neutral atoms and molecules of the dopant gas species. The ions are extracted from the arc chamber and then separated to select a target ionic species which is then directed towards the target substrate. The amount of ions produced depends upon various parameters of the arc chamber, including, but not limited to, the amount of energy supplied per unit time to the arc chamber, (i.e. power level) and flow rate of the dopant source and/or assistant species into the ion source.

Several dopant sources are currently in use today, such as, fluorides, hydrides, and oxides containing the dopant atom or molecule. These dopant sources can be limited in their ability to produce the beam current of the target ionic species and there is a continuous demand for improving the beam current, especially for high dose ion implantation applications, such as source drain/source drain extension implants, polysilicon doping and threshold voltage tuning.

Today, an increased beam current is achieved by introducing gases which produce ions containing the target dopant species into the plasma. One known method utilized for increasing the beam current generated from ionizing the dopant gas source is the addition of a co-species to the dopant source to produce more dopant ions. For example, U.S. Pat. No. 7,655,931 discloses adding a diluent gas having the same dopant ion as the dopant gas. However, the beam current increase may not be high enough for particular ion implant recipes. In fact, there have been instances where the addition of the co-species actually lowers the beam current. In this regard, U.S. Pat. No. 8,803,112 at FIG. 3 and Comparative Examples 3 and 4 demonstrate that adding a diluent of SiH4 or Si₂H₆, respectively, to a dopant source of SiF₄ actually lowered the beam current in comparison to the beam current generated solely from SiF₄.

Another method includes using isotopically enriched dopant sources. For example, U.S. Pat. No. 8,883,620 discloses adding isotopically enriched versions of a naturally occurring dopant gas, in an attempt to introduce more moles of the dopant ion per unit volume. However, utilizing isotopically enriched gases may require substantial changes to the ion implant process that can require re-qualification, which is a time consuming process. Additionally, the isotopically enriched version does not necessarily generate a beam current that increases in an amount that is proportional to the isotopic enrichment level. Further, isotopically enriched dopant sources are not readily commercially available. Even when commercially available, such sources can be significantly more expensive than their naturally occurring versions as a result of the process required to isolate the desired isotope of the dopant source above its natural abundance levels. This increase in cost of the isotopically enriched dopant source may sometimes not be justified in view of the observed increase in beam current, which for certain dopant sources has been only observed to produce a marginal improvement in beam current relative to its naturally occurring version.

In view of these drawbacks, there remains an unmet need for improving ion implant processes that have increased beam current.

### SUMMARY OF THE INVENTION

Due to these shortcomings, the present invention relates to a method of using a composition suitable for use in an ion implanter for production of a target ionic species to create an ion beam current, comprising a dopant source in combination with an assistant species wherein the dopant source and the assistant species occupy the ion implanter and interact therein to produce the target ionic species. The criteria for selecting an assistant species is based on the combination of the following properties: ionization energy, total ionization cross sections, bond dissociation energy to ionization energy ratio and a certain composition. It should be understood that other uses and benefits of the present invention will be applicable.

In one aspect, a method of increasing a beam current for implanting a non-carbon target ionic species, comprising the steps of: introducing a dopant source into an ion implanter from a delivery container; introducing an assistant species into the ion implanter from the delivery container, said assistant species comprising: (i) a lower ionization energy in comparison to an ionization energy of the dopant source; (ii) a total ionization cross-section (TICS) greater than 2 Å²; (iii) a ratio of bond dissociation energy (BDE) of a weakest bond of the assistant species to the lower ionization energy of the assistant species to be 0.2 or higher; and (iv) an absence of the non-carbon target ionic species; ionizing the assistant species to produce ions of the assistant species; the dopant source interacting with the assistant species whereby the dopant source undergoes assistant species ion-assisted ionization; forming a plasma containing ions; extracting a beam of the ions from the ion implanter; separating the ions to isolate non-carbon target ionic species; producing the beam current of the non-carbon target ionic species that is higher in comparison to that generated solely from the dopant source; and implanting the non-carbon target ionic species into a substrate.

In a second aspect, a method of producing an increased beam current for implanting a non-carbon target ionic species, comprising the steps of: introducing a dopant source into an ion implanter; introducing an assistant species into the ion implanter, said assistant species comprising: (i) \a lower ionization energy in comparison to an ionization energy of the dopant source; (ii) a total ionization cross-section (TICS) greater than 2 Å²; (iii) a ratio of bond dissociation energy (BDE) of a weakest bond of the assistant species to the lower ionization energy of the assistant species to be 0.2 or higher; and (iv) an absence of the non-carbon target ionic species; ionizing the assistant species to produce ions of the assistant species; the dopant source interacting with the assistant species whereby the dopant source undergoes assistant species ion-assisted ionization; forming a plasma containing ions; extracting a beam of the ions from the ion implanter; separating the ions to isolate non-carbon target ionic species; producing the increased beam current of the non-carbon target ionic species that is higher in comparison to that generated solely from the dopant source; and implanting the non-carbon target ionic species into a substrate.

### BRIEF DESCRIPTION OF THE DRAWINGS

FIG. 1 is a bar graph of relative ⁷²Ge ion beam current data for ⁷²GeF₄ gas mixtures;

FIG. 2 is a bar graph comparing the relative Ge ion beam current produced from naturally occurring GeF₄ and isotopically enriched ⁷²GeF₄ gas mixtures;

FIG. 3 is a bar graph of the relative beam current of ¹¹B ions generated from gas mixtures of isotopically enriched ¹¹BF₃;

Table 1 is an exemplary listing of assistant species with property values; and

Table 2 is an exemplary listing of assistant species and dopant species.

### DETAILED DESCRIPTION OF THE INVENTION

The relationship and functioning of the various elements of this invention are better understood by the following detailed description. The detailed description contemplates the features, aspects and embodiments in various permutations and combinations, as being within the scope of the disclosure. The disclosure may therefore be specified as comprising, consisting or consisting essentially of, any of such combinations and permutations of these specific features, aspects, and embodiments, or a selected one or ones thereof.

Unless indicated otherwise, it should be understood that all compositions are expressed as volume percentages (vol %), based on a total volume of the composition.

As used herein and throughout the specification, the terms “isotopically enriched” and “enriched” dopant gas are used interchangeably to mean the dopant gas contains a distribution of mass isotopes different from the naturally occurring isotopic distribution, whereby one of the mass isotopes has an enrichment level higher than present in the naturally occurring level. By way of example, 58% ⁷²GeF₄ refers to an isotopically enriched or enriched dopant gas containing mass isotope ⁷²Ge at 58% enrichment, whereas naturally occurring GeF₄ contains mass isotope ⁷²Ge at 27% natural abundance levels. Isotopically enriched ¹¹BF₃ as used herein and throughout refers to an isotopically enriched dopant gas containing mass isotope ¹¹B at preferably 99.8% enrichment, whereas natural occurring BF₃ contains mass isotope ¹¹B at 80.1% natural abundance levels. The enrichment levels as used herein and throughout are expressed as volume percentages, based on a total volume of distribution of the mass isotopes contained in the material.

It should be understood that the dopant source and the assistant species as described herein and throughout may include other constituents (e.g., unavoidable trace contaminants) whereby such constituents are contained in an amount that does not adversely impact the interaction of the assistant species with the dopant source.

The present disclosure relates to a composition for ion implantation comprising a dopant source and an assistant species wherein the assistant species in combination with the dopant gas produces an ion beam current of the desired dopant ion with or without an optional diluent species. The “target ionic species” is defined as any positively or negatively charged atom or molecular fragment(s) originating from the dopant source that is implanted into the surface of a target substrate, including but not limited to, wafers. As will be explained, the present invention recognizes that there is a need for improvement of current dopant sources, particularly in high dose applications (i.e., greater than 10¹³ atoms/cm²) of ion implantation, and offers a novel solution for achieving the same.

It should be understood that reference to dopant source and assistant species may also include any isotopically enriched versions of either the dopant source or assistant species, whereby any atom of the dopant source or the assistant species is isotopically enriched greater than natural abundance levels.

In one aspect, the present invention involves a dopant source comprising the target ionic species and an assistant species comprising the following attributes: (i) a lower ionization energy than the dopant source; (ii) a total ionization cross section greater than 2 Å² (iii) a ratio of bond dissociation energy to ionization energy greater than or equal to 0.2; and (iv) a composition characterized by an absence of the target ionic species. Without being bound by any particular theory, the Applicants have discovered that when an assistant species is selected with the criteria above and co-flowed, sequentially flowed or mixed with a dopant source, the resultant composition can interact with each other to produce the target ionic species with or without an optional diluent species.

In another aspect, the present invention involves a non-carbon dopant source comprising the target ionic species and an assistant species comprising the following attributes: (i) a lower ionization energy than the non-carbon dopant source; (ii) a total ionization cross section greater than 2 Å² (iii) a ratio of bond dissociation energy to ionization energy greater than or equal to 0.2; and (iv) a composition characterized by an absence of the target ionic species. The non-carbon dopant source and the assistant species occupy the ion implanter and interact therein to produce the target ionic species.

Without being bound by any particular theory, the Applicants have discovered that when an assistant species is selected with the criteria above and co-flowed, sequentially flowed or mixed with a dopant source, the resultant composition can interact with each other to produce the target ionic species with or without an optional diluent species.

In yet another aspect, the present invention involves a dopant source comprising a non-carbon target ionic species and an assistant species comprising the following attributes: (i) a lower ionization energy than the non-carbon dopant source; (ii) a total ionization cross section greater than 2 Å² (iii) a ratio of bond dissociation energy to ionization energy greater than or equal to 0.2; and (iv) a composition characterized by an absence of the non-carbon target ionic species. The dopant source and the assistant species occupy the ion implanter and interact therein to produce the non-carbon target ionic species.

In another aspect, the dopant source and the assistant species (having the criteria described herein) can interact with each other to produce a higher ion beam current of the non-carbon target ionic species than that generated solely from the dopant source. The ability to produce a higher beam current of the non-carbon target ionic species is surprising, given that the assistant species does not contain the target ionic species and, as a result, is diluting the dopant source and reducing the number of dopant source molecules introduced into the plasma. The assistant species enhances the ionization of the dopant source into forming the desired or non-carbon target ionic species to enable increase of the beam current of the non-carbon target ionic species from the dopant source even though the assistant species does not include the non-carbon target ionic species.

In another aspect, the dopant source is a non-carbon dopant source and the assistant species (having the criteria described herein) can interact with each other to produce a higher ion beam current of the target ionic species than that generated solely from the non-carbon dopant source. The ability to produce a higher beam current of the target ionic species is surprising, given that the assistant species does not contain the target ionic species and, as a result, is diluting the non-carbon dopant source and reducing the number of non-carbon dopant source molecules introduced into the plasma. The assistant species enhances the ionization of the non-carbon dopant source into forming the desired or target ionic species to enable increase of the beam current of the target ionic species from the non-carbon dopant source even though the assistant species does not include the target ionic species.

In yet another aspect, the present invention involves a dopant source comprising the target ionic species and an assistant species comprising the following attributes: (i) a lower ionization energy than the dopant source; (ii) a total ionization cross section greater than 2 Å² (iii) a ratio of bond dissociation energy to ionization energy greater than or equal to 0.2; and (iv) a composition characterized by an absence of the target ionic species. Without being bound by any particular theory, the Applicants have discovered that when an assistant species is selected with the criteria above and co-flowed, sequentially flowed or mixed with the dopant source, the resultant composition can interact with each other to produce the target ionic species which creates the ion beam current having a higher level than that generated solely from the dopant source, with or without an optional diluent species.

The assistant species can be mixed with the dopant source in a single storage container. Alternatively, the assistant species and dopant source can be co flown from separate storage containers. Still further, the assistant species and dopant source can be sequentially flowed from separate storage containers. When co-flown or sequentially flowed, the resultant compositional mixture can be produced upstream of the ion chamber or within the ion source chamber. In another example, the compositional mixture is withdrawn in the vapor or gas phase and then flows into an ion source chamber where the gas mixture is ionized to create a plasma. The target ionic species can then be extracted from the plasma and implanted into the surface of a substrate.

The ionization energy as used herein refers to the energy required to remove an electron from an isolated gas species and form a cation. The values for ionization energy can be obtained from the literature. More specifically, the literature sources can be found in the National Institute of Standards and Technology (NIST) chemistry webbook (P. J. Linstrom and W. G. Mallard, Eds., NIST Chemistry WebBook, NIST Standard Reference Database Number 69, National Institute of Standards and Technology, Gaithersburg Md., 20899. http://webbook.nist.gov/chemistry/). Values for ionization energy can be determined experimentally using electron impact ionization, photoelectron spectroscopy, or photoionization mass spectrometry. Theoretical values for ionization energy can be obtained using density functional theory (DFT) and modeling software, such as commercially available Dacapo, VASP, and Gaussian. Although the energy supplied to the plasma is a discrete value, the species in the plasma are present over a broad distribution of different energies. When an assistant species with a lower ionization energy than the dopant source is added or introduced with the dopant source, the assistant species can ionize over a larger distribution of energies in the plasma. As a result, the overall population of ions in the plasma can increase. Such an increased population of ions leads to “assistant species ion-assisted ionization” of the dopant species as a result of the ions of the assistant species accelerating in the presence of the electric field and colliding with the dopant source to further break it down into more fragments. The net result is an increase in beam current for the target ionic species. On the contrary, if a species with a higher ionization energy than the dopant source is introduced into the dopant source, the added species can form a lower percentage of ions compared to the ions generated from the dopant source which can reduce the overall percentage of ions in the plasma and can reduce the beam current of the target ionic species. In one embodiment, the ionization energy of the assistant species is at least 5% lower than the ionization energy of the dopant source.

Although having an assistant species with a lower ionization energy than the dopant source is desirable, the lower ionization energy by itself may not increase beam current. Other applicable criteria must be met in accordance with the principles of the present invention. Specifically, the assistant species must have a minimum total ionization cross section. The total ionization cross section (TICS) of a molecule or atom as used herein is defined as the probability of the molecule or the atom forming an ion under electron and/or ion impact ionization represented in units of Area (e.g., cm², A², m²) as a function of the electron energy in eV. It should be understood that TICS as used herein and throughout refers to a maximum value at a particular electron energy. Experimental data and BEB estimates are available in the literature and through the National Institute of Standards and Technology (NIST) database (Kim, Y., K. et al., Electron-Impact Cross Sections for Ionization and Excitation Database 107, National Institute of Standards and Technology, Gaithersburg Md., 20899, http://physics.nistgov/PhysRefData/Ionization/molTable.html.) TICS values can be determined experimentally using electron impact ionization or electron ionization dissociation. The TICS can be estimated theoretically using the binary encounter Bethe (BEB) model. As the number of collision events in the plasma increases, the number of bonds broken increases and the number of ion fragments increases. Hence, besides a lower ionization energy, the present invention has discovered that a sufficient total ionization cross-section for the assistant species is also a desired property to assist with the ionization of the dopant species. In a preferred embodiment, the assistant species has a TICS that is greater than 2 Å². Applicants have discovered that an ionization cross-section greater than 2 Å² provides sufficient likelihood that the necessary collisions can occur. On the contrary, if the ionization cross section is less than 2 Å², applicants have discovered that the number of collision events in the plasma is expected to decrease and, as a result, the beam current can also decrease. As an example, H₂ has a total ionization cross section less than 2 Å², and when added to a dopant source such as GeF₄, the beam current of Ge⁺ is observed to decrease relative to that generated solely from GeF₄. In other embodiments, the total ionization cross-section of the desired assistant species is greater than 3 Å²; greater than 4 Å²; or greater than 5 Å². In addition to the requisite ionization energy and TICS, the assistant species that is selected must also have a certain bond dissociation energy (BDE) such that a ratio of the BDE of a weakest bond of the assistant species to the ionization energy of the assistant species is 0.2 or higher. Values for BDE are readily available in the literature, and more specifically from the National Bureau of Standards (Darwent, B. deB., “Bond Dissociation Energies in Simple Molecules”, National Bureau of Standards, (1970)) or from textbooks (Speight, J. G., Lange, N. A., Lange's Handbook of Chemistry, 16^{th} ed., McGraw-Hill, 2005). BDE values can also be experimentally determined through techniques such as pyrolysis, calorimetry, or mass spectrometry and also can be determined theoretically through density functional theory and modeling software such as Dacapo, VASP, and Gaussian. The ratio is an indicator of the proportion of ions produced in the plasma relative to uncharged species. The BDE can be defined as the energy required to break a chemical bond. The bond with the weakest BDE will be the most likely to initially break in the plasma. Therefore, this metric is calculated using the weakest bond dissociation energy in the molecule, as each molecule can have multiple bonds with differing energies.

Generally speaking, in a plasma, chemical bonds are broken by collisions to produce molecular fragments. For example, GeF₄ can break apart into Ge, GeF, GeF₂, and GeF₃ and F fragments. If Ge is the target ionic species, then four Ge—F bonds must be broken to produce the Ge target ionic species. Conventional wisdom dictates that a molecule with a lower bond dissociation energy is preferable, as it would more easily form the target ionic species because the chemical bonds would break more easily. However, the applicants have discovered otherwise. It has been discovered that molecules with a higher BDE tend to produce a greater proportion of ions compared to free radicals and/or neutrals. When a chemical bond is broken specifically in a plasma, the resulting species will form either ions, free radicals, or neutral species. The ratio of BDE of the weakest bond to ionization energy is selected in accordance with the principles of the present invention so as to increase the proportion of ions in the plasma while reducing the proportion of free radicals and neutral species, as both the free radicals and neutral species have no charge and, therefore, are not influenced by electric fields or magnetic fields. Further, these species are inert in a plasma and cannot be extracted to form an ion beam. Accordingly, the ratio of the BDE of the weakest bond of the assistant species to the ionization energy is an indicator of the fraction of ions formed in the plasma relative to the free radicals and neutral species. Specifically, when a gas molecule with a bond dissociation of the weakest bond to ionization energy ratio of 0.2 or higher is added to a dopant source, the plasma is more likely to produce a greater proportion of ions compared to free radical and neutral species in the plasma. The greater proportion of ions can increase the beam current of the target ionic species. In another embodiment, the assistant species is selected to have a weakest bond dissociation energy to ionization energy ratio of at least 0.25 or higher; and preferably 0.3 or higher. On the contrary, if the ratio of bond dissociation energy of the weakest bond to ionization energy is below 0.2, the energy supplied to the plasma is coupled to forming a higher proportion of neutral species and/or free radicals which can flood the plasma and decrease the number of target ionic species produced. Hence, this non-dimensional metric of the present invention allows a better comparison between the ability of species to produce a higher proportion of ions relative to free radicals and/or neutrals in the plasma.

The assistant species has a composition that is characterized by an absence of the target ionic species. In this regard, Table 2 shows several examples of dopant sources with target ionic species along with examples of suitable assistant species for each dopant source based on the four criteria of ionization energy, TICS and weakest BDE to ionization energy ratio and where the assistant species does not contain the target ionic species. Table 2 comprises examples of suitable assistant species for each dopant source (as indicated by “X”), but it should be understood that the present invention contemplates any species that satisfies the criteria described previously. As can been seen in Table 2, the assistant species does not contain the target ionic species. The ability to utilize such assistant species is unexpected, as less moles of dopant source per unit volume is introduced into the plasma, and thus has the effect of diluting the dopant source in the plasma. However, when the assistant species meets the criteria described previously, the assistant species, when added to the dopant source or vice versa, can increase the beam current of the target ionic species compared to the beam current generated solely from the dopant source. The assistant species enhances the formation of the target ionic species from the dopant source to increase the ion beam current of the target ionic species. The increase in beam current may be 5% or higher; 10% or higher; 20% or higher; 25% or higher; or 30% or higher. The exact percentage by which the ion beam current is increased can be a result of selected operating conditions, such as, by way of example, power level of the ion implanter and/or flow rate of the dopant source and/or the assistant species gases introduced into the ion implanter.

A preferred assistant species to enhance the beam current of the target ionic species from the dopant source has a lower ionization energy than the dopant source; a total ionization cross-section greater than 2 Å² at the same operating conditions as the dopant source and a weakest bond dissociation energy to ionization energy ratio of 0.2 or higher. Table 1 shows a tabular listing of select assistant species and their respective numerical values for TICS, ionization energy and BDE/IE ratio. The TICS values shown in Table 1 are published values that are obtained from either the Electron-Impact Cross Sections for Ionization and Excitation Database 107 from NIST; or from Bull, S. et al., J. Phys. Chem. A (2012) 116, pp 767-777. Ionization energy values for each molecule in Table 1 are obtained from the NIST Chemistry WebBook or NIST Standard Reference Database Number 69 (i.e., specifically, the most recent published version as of the filing date of the present invention). The ionization values were based on electron impact ionization, which was the experimental technique used to obtain such values. BDE values used in the calculation of the BDE/IE ratio were obtained from the National Bureau of Standards or “Lange's Handbook of Chemistry” cited hereinbefore. Table 1 comprises examples of suitable assistant species but any species that follows the criteria described herein in accordance with the principles of the present invention can be utilized. The assistant species does not contain the target ionic species as the purpose of the assistant species is to enhance formation of the target ionic species from the dopant source. The combination of suitable assistant species and dopant source preferably can generate an ion beam capable of doping at least 10¹¹ atoms/cm² of the target ionic species from the dopant source.

Suitable dopant source and assistant species are now described, with reference to Table 2. An example of a dopant source compound is GeF₄ for Ge ion implantation. GeF₄ has an ionization energy of 15.7 eV and a weakest bond dissociation energy to ionization energy ratio of 0.32. In accordance with the principles of the present invention, an example of an assistant species is CH₃F. CH₃F has an ionization energy of 13.1 eV which is lower than GeF₄, a TICS of 4.4 Å², and a weakest bond dissociation energy for the C—H bond to ionization energy ratio of 0.35. For GeF₄, the assistant species will preferably have a TICS of at least 3 Å², and a ratio of BDE of the weakest bond to ionization energy of 0.22 or greater.

Another example of a dopant source compound is SiF₄ for Si ion implantation. This molecule has an ionization energy of 16.2 eV and a weakest bond dissociation energy to ionization energy ratio of 0.35. An example assistant species is CH₃Cl. This molecule has an ionization energy of 11.3 eV which is lower than SiF₄, a TICS of 7.5 Å², and a weakest bond dissociation energy for the C—Cl bond to ionization energy ratio of 0.31. For SiF₄, the assistant species will preferably have a TICS of at least 4 Å², and a ratio of BDE of the weakest bond to ionization energy of 0.25 or greater.

Another example of a dopant source compound is BF₃ for BF₂ and B ion implantation. This molecule has an ionization energy of 15.8 eV and a weakest bond dissociation energy to ionization energy ratio of 0.37. An example assistant species is Si₂H₆. This molecule has an ionization energy of 9.9 eV which is lower than BF₃, a TICS of 8.1 Å², and for the Si—H bond a weakest bond dissociation energy to ionization energy ratio of 0.31. For BF₃, the assistant species will preferably have a TICS of at least 3 Å², and a ratio of BDE of the weakest bond to ionization energy of 0.23 or greater.

Another example of a dopant source compound is CO for C⁺ ion implantation. This molecule has an ionization energy of 14.02 eV and a bond dissociation energy to ionization energy ratio of 0.8. An example assistant species is GeH₄, which has an ionization energy of 10.5 eV, a TICS of 5.3 Å², and a weakest bond dissociation energy to ionization energy ratio of 0.32. For CO, the assistant species will preferably have a maximum TICS of at least 2.7 Å², and a ratio of BDE of the weakest bond to ionization energy of 0.25 or greater.

Another aspect of the disclosure relates to choosing a dopant source that contains, for example, but not limited to, germanium, boron, silicon, nitrogen, arsenic, selenium, antimony, indium, sulfur, tin, gallium, aluminum, or phosphorous atoms contained in the target ionic species and then selecting an assistant species having the attributes (i) through (iv) mentioned hereinbefore, and further whereby the assistant species contains one or more functional groups selected from the following: alkanes, alkenes, alkynes, haloalkanes, haloalkenes, haloalkynes, thiols, nitriles, amines, or amides.

In another aspect of the present invention, the operating conditions of the ion source can be adjusted such that the composition of the dopant source and assistant species is configured to generate an ion beam current that is the same or less than the ion beam current generated solely from the dopant source with or without an optional diluent. Operating at such beam current levels can create other operational benefits. By way of example, some of the operational benefits include but are not limited to reduction of beam glitching, increased beam uniformity, limited space charge effects and beam expansion, limited particle formation, and increased source lifetime of the ion source, whereby all such operational benefits are being compared to sole use of the dopant source. The operational conditions which may be manipulated, include, but are not limited to, arc voltage, arc current, flow rate, extraction voltage and extraction current or any combination thereof. Additionally, the ion source may include use of one or more optional diluent, which can include H₂, N₂, He, Ne, Ar, Kr, and/or Xe.

It should be understood that the ions produced from ionization of the assistant species can be selected to be implanted into the target substrate.

Various operating conditions can be used to carry out the present invention. For example, the arc voltage can be in a range of 50-150 V; the flow rate of each of the dopant gas and assistant species into the ion implanter can be in in a range of 0.1-100 sccm; and the extraction voltage can be in a range of 500V to 50 kV. Preferably, each of these operating conditions is selected to achieve a source life of at least 50 hours; with an ion beam current between 10 microamps and 100 mA.

Various compositions for the assistant species are contemplated. For example, in another aspect of the present invention relates to assistant species that have attributes (i) through (iv) mentioned hereinbefore and have a representative formula CH_{y}X_{4-y} where X is any halogen and y=0 to 4. Examples of these species include but are not limited to CH₄, CF₄, CCl₄, CH₃Cl, CH₃F, CH₂Cl₂, CHCl₃, CH₂F₂, CHF₃, CH₃Br, CH₂Br₂, or CHBr₃. Another aspect of the present invention relates to assistant species that have attributes (i) through (iv) mentioned hereinbefore and has the formula CHᵢFⱼCl_{y}Br_{z}I_{q} where i, j, y, z, and q range from 0 to 4 and i+j+y+z+q=4. Examples of these species include but are not limited to CClF₃, CH₂ClF, CHF₂Cl, CHCl₂F, CCl₂F₂, and CCl₃F. Another aspect of the present invention relates to assistant species that have attributes (i) through (iv) mentioned hereinbefore and has the formula CᵢHⱼN_{y}X_{z} where X is any halogen species, i ranges from 1 to 4, y and z, range from 0 to 4, and the value of j varies such that each atom has a closed shell of valence electrons. Examples of these species include but are not limited to CH₃CN, CF₃CN, HCN, CH₂CF₄, CH₃CF₃, C₂H₆, and CH₃NH₂. Another aspect of the present invention relates to assistant species that have attributes (i) through (iv) mentioned hereinbefore and has the formula Si_{q}H_{y}X_{z} where X is any halogen species, q ranges from 1 to 4, y, and z, range from 0 to 4, and the values of y and z vary such that each atom has a closed shell of valence electrons. Examples of these species include but are not limited to SiH₄, Si₂H₆, SiH₃Cl, and SiH₂Cl₂.

Still further, other assistant species may include CS₂, GeH₄, Ge₂H₆, or B₂H₆, each of which is paired with a particular dopant source in accordance with the principles of the present invention and as shown in Table 2.

The present invention contemplates various fields of use for the compositions described herein. For example, some methods include but are not limited to beam line ion implantation and plasma immersion ion implantation mentioned in U.S. Pat. No. 9,165,773, which is incorporated herein by reference in its entirety. Further, it should be understood that the compositions disclosed herein may have utility for other applications besides ion implantation, in which the primary source comprises a target species and the assistant species does not contain the target species and is further characterized as meeting the criteria (i), (ii) and (iii) mentioned hereinbefore. For example, the compositions may have applicability for various deposition processes, including, but not limited to, chemical vapor deposition or atomic layer deposition.

The compositions of the present invention can also be stored and delivered from a container with a vacuum actuated check valve that can be used for sub atmospheric delivery, as described in U.S. patent application with Docket No. 14057-US-P1, which is incorporated herein by reference in its entirety. Any suitable delivery package may be employed, including those described in U.S. Pat. Nos. 5,937,895; 6,045,115; 6,007,609; 7,708,028; 7,905,247; and U.S. Ser. No. 14/638,397 (U.S. Patent Publication No. 2016-0258537), each of which is incorporated herein by reference in its entirety. When the compositions of the present invention are stored as a mixture, the mixture in the storage and delivery container may also be present in the gas phase; a liquid phase in equilibrium with the gas phase wherein the vapor pressure is high enough to allow flow from the discharge port; or an adsorbed state on a solid media, each of which is described in U.S. patent application with Docket No. 14057-US-P1. Preferably, the composition of assistant species and dopant source will be able to generate a beam of the target ionic species to implant of 10¹¹ atoms/cm² or higher.

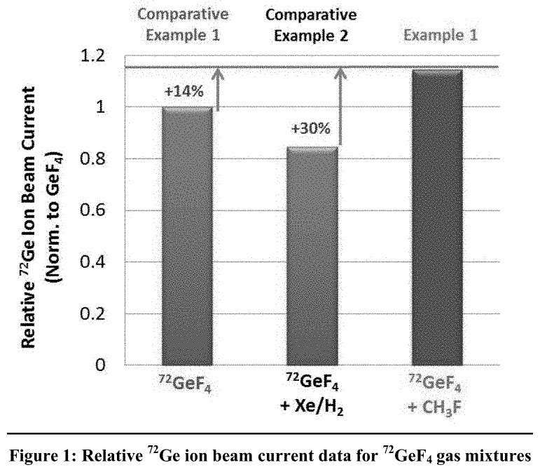

Applicants have performed several experiments as a proof of concept using GeF₄ as a dopant source and CH₃F as an assistant species. In each experiment, the ion beam performance was measured using the Ge ion beam current produced; and the weight change of components was measured within the ion source chamber to measure the performance of the ion source. A cylindrical ion source chamber was used to generate a plasma. The ion source chamber consisted of a helical tungsten filament, tungsten walls, and a tungsten anode perpendicular to the axis of the helical filament. A substrate plate was positioned in front of the anode to keep the anode stationary during the ionization process. A small aperture in the center of the anode and a series of lenses placed in front of the anode were used to generate an ion beam from the plasma and a velocity filter was used to isolate specific ion species from the ion beam. A faraday cup was used to measure the current from the ion beam and all tests were run at an arc voltage of 100 V. The extraction voltage was the same value for each experiment. The entire system was contained in a vacuum chamber capable of reaching pressures less than 1e-7 Torr. FIG. 1 shows a bar graph of the ⁷²Ge ion beam current relative to the ⁷²Ge ion beam current produced solely by ⁷²GeF₄ for each gas mixture tested.

### Comparative Example 1 (⁷²GeF₄)

A test was performed to determine the ion beam performance of the dopant gas composition of ⁷²GeF₄ that was isotopically enriched to 50.1 vol %. The ⁷²GeF₄ was introduced into the ion source chamber. A current was applied to the filament to generate electrons and a voltage was applied to the anode to ionize the ⁷²GeF₄ and produce ⁷²Ge ions. The ⁷²Ge ion beam current was normalized to be the basis for comparing the ⁷²Ge ion beam current of other gas mixtures. Results are shown at FIG. 1. A significant filament weight gain occurred of 160 milligrams after 52 minutes of operation at which point the experiment was terminated as the filament could no longer sustain a plasma after 52 minutes. This was equivalent to a filament weight gain rate of 185 mg/hr.

### Comparative Example 2 (75 vol % ⁷²GeF₄+25 vol % Xe/H₂)

Another test was performed to determine the ion beam performance of the dopant gas composition of 75 vol % ⁷²GeF₄ (isotopically enriched in mass isotope ⁷²Ge to 50.1 vol %) mixed with 25 vol % Xe/H₂. The same ion source chamber was utilized as that in Comparative Example 1. The ⁷²GeF₄ and Xe/H₂ were introduced from separate storage containers and mixed before entering the ion source chamber. A current was applied to the filament to generate electrons and a voltage was applied to the anode to ionize the gas mixture and produce ⁷²Ge ions. The ⁷²Ge ion beam current was measured and determined to be about 16% less than the ⁷²Ge ion beam current produced solely using ⁷²GeF₄. Results are shown at FIG. 1. A weight loss of 30 milligrams was observed for the filament over the course of 15 hours of operation. The weight change of the filament with time was roughly −2 mg/hour which indicated a significant improvement over ⁷²GeF₄.

### Example 1 (75 vol % ⁷²GeF₄+25 vol % CH₃F)

Another test was performed to determine the ion beam performance of the dopant gas composition of 75 vol % ⁷²GeF₄ (isotopically enriched in mass isotope 72Ge to 50.1 vol %) mixed with 25 vol % CH₃F. The same ion source chamber was utilized as that in Comparative Example 1. The ⁷²GeF₄ and CH₃F were introduced from separate storage containers and mixed before entering the ion source chamber. A current was applied to the filament to generate electrons and a voltage was applied to the anode to ionize the gas mixture and produce ⁷²Ge ions. The ⁷²Ge ion beam current was measured and determined to be about 14% greater than the ⁷²Ge ion beam current produced using solely ⁷²GeF₄ and 30% greater than the ⁷²Ge ion beam current generated with 75 vol % ⁷²GeF₄ mixed with 25 vol % Xe/H₂. The results are shown in FIG. 1. A weight loss of 16 milligrams was observed over the course of 12 hours of operation or −1.33 mg/hr indicating a significant improvement over ⁷²GeF₄ and similar behavior to the 75 vol % ⁷²GeF₄ mixed with 25 vol % Xe/H₂.

The results of the experiments in FIG. 1 show that although CH₃F diluted the volume of GeF₄, it improved the Ge ion beam current significantly while also improving the performance of the ion source compared to solely using GeF₄. Relative to the mixture in Comparative Example 1, the addition of Xe/H₂ improved the performance of the ion source but reduced the Ge ion beam current compared to the Ge ion beam current produced solely from GeF₄.

### Comparative Example 3 (50 vol % ⁷²GeF₄+50 vol % Xe/H₂)

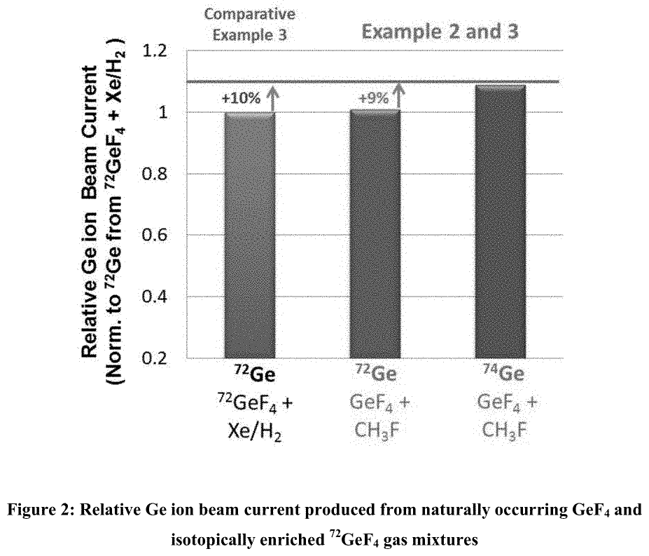

Another test was performed to determine the ion beam performance of the dopant gas composition of 50 vol % ⁷²GeF₄ (isotopically enriched in mass isotope ⁷²Ge to 50.1 vol %) mixed with 50 vol % Xe/H₂. The same ion source chamber was utilized as for all previous examples. The ⁷²GeF₄ and Xe/H₂ were introduced from separate storage containers and mixed before entering the ion source chamber. A current was applied to the filament to generate electrons and a voltage was applied to the anode to ionize the gas mixture and produce ⁷²Ge ions. The flow rate of ⁷²GeF₄ in this experiment was significantly higher than the previous examples, thereby making relevant Ge-containing ion beam current comparisons not possible. The ⁷²Ge ion beam current from this mixture was normalized to compare the ⁷²Ge and ⁷⁴Ge ion beam currents from the naturally occurring GeF₄ mixtures shown in FIG. 2. Under the operating conditions in these experiments, the ⁷²Ge ion beam current from 50 vol % ⁷²GeF₄+50 vol % Xe/H₂ and 75 vol % ⁷²GeF₄+25 vol % Xe/H₂ were equivalent. Results are shown in FIG. 2. A weight gain rate of 0.78 mg/hr was observed, which was significantly lower than the weight gain of 185 mg/hr for ⁷²GeF₄ and comparable to the weight loss of 2 mg/hr of 75 vol % ⁷²GeF₄ (isotopically enriched) mixed with 25 vol % Xe/H₂.

### Examples 2 and 3 (70 vol % GeF₄+30 vol % CH₃F)

Another test was performed to determine the ion beam performance of the dopant gas composition of 70 vol % natural GeF₄ mixed with 30 vol % CH₃F. The same ion source chamber was utilized as for previous examples. The natural GeF₄ and CH₃F were introduced from separate storage containers and mixed before entering the ion source chamber. A current was applied to the filament to generate electrons and a voltage was applied to the anode to ionize the gas mixture and produce both ⁷²Ge and ⁷⁴Ge ions. The natural GeF₄ had a level for ⁷²Ge of 27.7% and a level for ⁷⁴Ge of 35.9%, whereas the isotopically enriched ⁷²GeF₄ was enriched in ⁷²Ge to 50.1% while the ⁷⁴Ge had a level of 23.9%. The Ge ion beam current of both ⁷²Ge and ⁷⁴Ge was measured. Both results are shown in FIG. 2 relative to the ⁷²Ge ion beam current from 50 vol % ⁷²GeF₄ mixed with 50 vol % Xe/H₂ of Comparative Example 3. The ion beam current of ⁷⁴Ge from 70 vol % natural GeF₄ with 30 vol % CH₃F was 10% higher than the ⁷²Ge ion beam current generated from 50 vol % isotopically enriched ⁷²GeF₄ with 50 vol % Xe/H₂.

A weight gain rate of 2 mg/hr was observed over the course of operation which was similar in behavior to the weight gain of 0.78 mg/hr for 50 vol % isotopically enriched ⁷²GeF₄ with 50 vol % Xe/H₂.

The results of FIG. 2 were surprising given that the level of ⁷²Ge enrichment in isotopically enriched ⁷²GeF₄ was 14.2 vol % higher than ⁷⁴Ge in naturally occurring GeF₄. It was also surprising that the ⁷²Ge ion beam current from both mixes (Comparative Example 3 and Examples 2 and 3) were observed to be within 1% of each other given that the enrichment level in ⁷²GeF₄ was 22.4 vol % higher than in natural GeF₄, and conventional wisdom would have expected the mixture of 50 vol % Xe/H₂ with 50 vol % enriched ⁷²GeF₄ to produce a higher beam current.

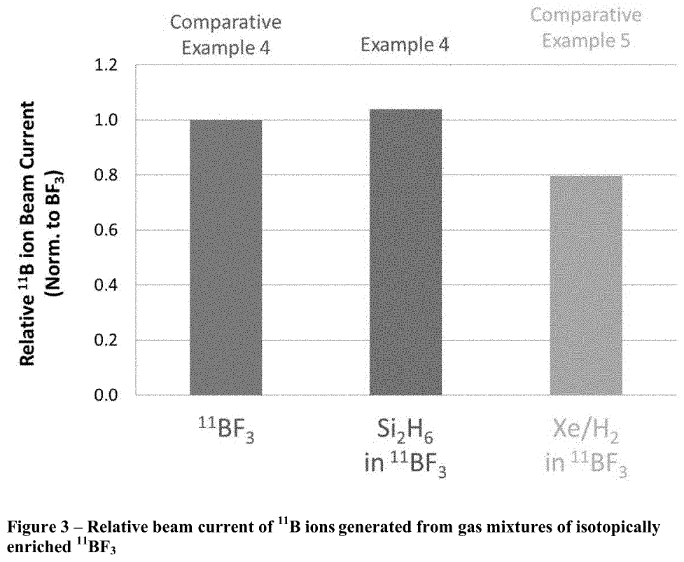

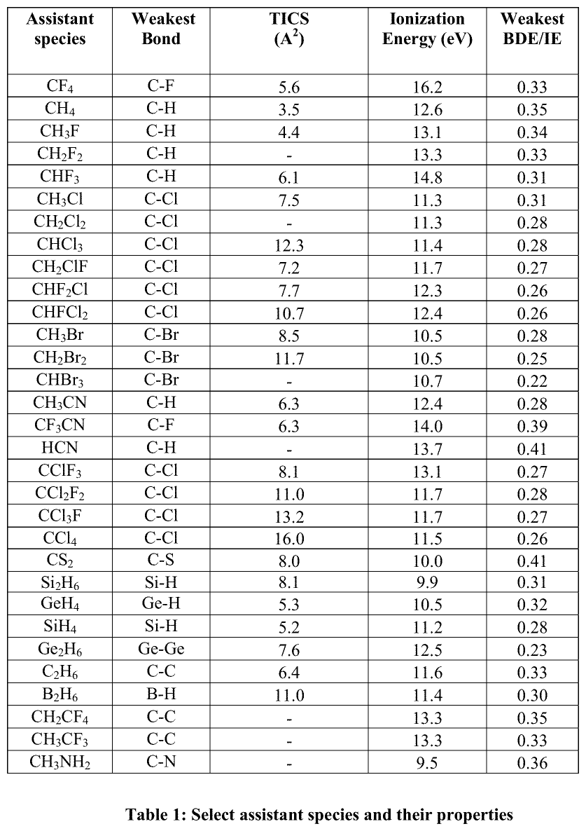

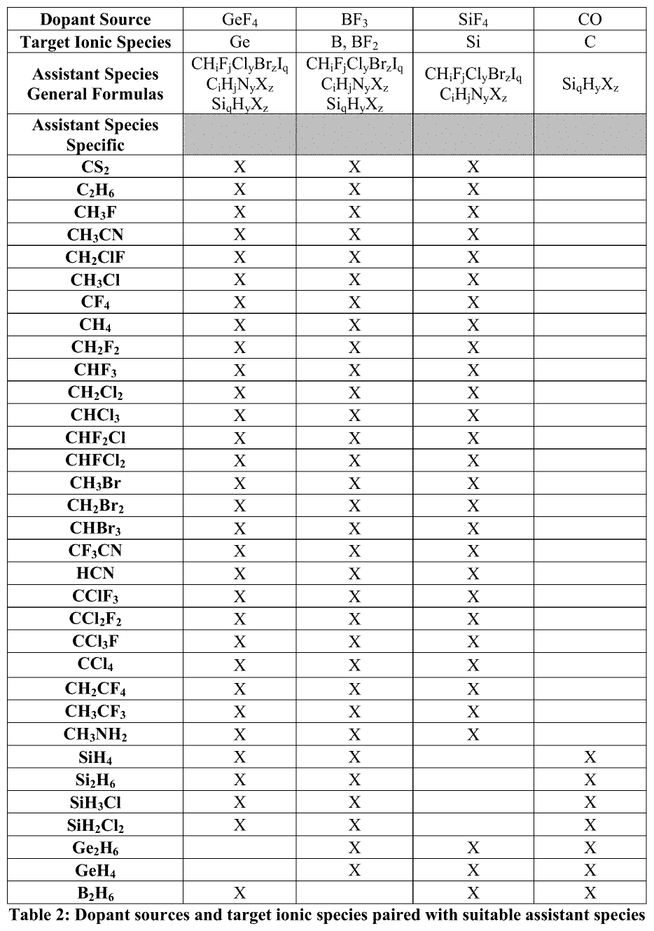

Applicants have performed several additional experiments as a proof of concept using ¹¹BF₃ as a dopant source and Si₂H₆ as an assistant species. In each experiment, the ion beam performance was measured using the ¹¹B ion beam current produced. A cylindrical ion source chamber was used to generate a plasma. The ion source chamber consisted of a helical tungsten filament, tungsten walls, and a tungsten anode perpendicular to the axis of the helical filament. A substrate plate was positioned in front of the anode to keep the anode stationary during the ionization process. A small aperture in the center of the anode and a series of lenses placed in front of the anode were used to generate an ion beam from the plasma and a velocity filter was used to isolate specific ion species from the ion beam. A faraday cup was used to measure the current from the ion beam and all tests were run at an arc voltage of 120 V. The extraction voltage was the same value for each experiment. The entire system was contained in a vacuum chamber capable of reaching pressures less than 1e-7 Torr. FIG. 3 shows a bar graph of the beam current of ¹¹B— ions relative to the beam current of ¹¹B ions solely produced by ¹¹BF₃ for each gas mixture tested.

### Comparative Example 4—¹¹BF₃

A test was performed to determine the ion beam performance of isotopically enriched ¹¹BF₃ as a dopant gas. ¹¹BF₃ was introduced into the ion source chamber from a single bottle. A current was applied to the filament to generate electrons and a voltage was applied to the anode to ionize the mixture and produce ions. The settings of the ion source were adjusted to maximize the beam current of ¹¹B ions. The beam current of ¹¹B ions was normalized (as shown in FIG. 3) to be the basis for comparing against the beam current of ¹¹B ions from other gas mixtures.

### Comparative Example 5—¹¹BF₃ with Xe/H₂

Another test was performed to determine the ion beam performance of the dopant gas composition of Xe/H₂ mixed with isotopically enriched ¹¹BF₃. The same ion source chamber was utilized as for ¹¹BF₃ in Comparative Example 4. The mixture of Xe/H₂ and ¹¹BF₃ was generated from a bottle of pure ¹¹BF₃ and a bottle of Xe/H₂ introduced from separate storage containers and mixed before entering the ion source chamber. A current was applied to the filament to generate electrons and a voltage was applied to the anode to ionize the gas mixture and produce ¹¹B ions. The settings of the ion source were adjusted to maximize the beam current of ¹¹B ions. The mixture of ¹¹BF₃ with Xe/H₂ produced a maximum beam current of ¹¹B ions that was 20% lower than the beam current of ¹¹B ions solely produced by ¹¹BF₃ in Comparative Example 4.

### Example 4—¹¹BF₃ with Si₂H₆

Another test was performed to determine the ion beam performance of the dopant gas composition of Si₂H₆ mixed with isotopically enriched ¹¹BF₃. The same ion source chamber was utilized as for ¹¹BF₃ in Comparative Example 4. The mixture of Si₂H₆ with ¹¹BF₃ was generated from a bottle of ¹¹BF₃ and a mixture of Si₂H₆ in ¹¹BF₃ introduced from separate storage containers and mixed before entering the ion source chamber. A current was applied to the filament to generate electrons and a voltage was applied to the anode to ionize the gas mixture and produce ¹¹B ions. The settings of the ion source were adjusted to maximize the beam current of ¹¹B ions and the beam current of ¹¹B ions was measured for both mixtures. The mixture Si₂H₆ balanced with ¹¹BF₃ generated an ¹¹B ion beam current 4% greater than the ¹¹B ion beam current produced solely from ¹¹BF₃ in Comparative Example 4. The results from Si₂H₆ in ¹¹BF₃ are unexpected given that the Si₂H₆ added to ¹¹BF₃ is diluting the concentration of boron in the gas mixture and Si₂H₆ contains no boron atoms to contribute to the increase in the beam current exhibited by the mixture.

The results of these tests show that although the addition of Si₂H₆ is diluting the volume of ¹¹BF₃, it improves the beam current of ¹¹B ions compared to using pure ¹¹BF₃. The addition of Xe/H₂ does not have the same effect as Si₂H₆ and instead dilutes the ¹¹BF₃ to an extent that the beam current of ¹¹B ions is reduced compared to the ¹¹B ion beam current produced solely from ¹¹BF₃.

While it has been shown and described what is considered to be certain embodiments of the invention, it will, of course, be understood that various modifications and changes in form or detail can readily be made without departing from the spirit and scope of the invention. It is, therefore, intended that this invention not be limited to the exact form and detail herein shown and described, nor to anything less than the whole of the invention herein disclosed and hereinafter claimed.

TABLE 1
Select assistant species and their properties

| Assistant | Weakest | TICS | Ionization | Weakest |
|---|---|---|---|---|
| species | Bond | (A²) | Energy (eV) | BDE/IE |
| CF₄ | C—F | 5.6 | 16.2 | 0.33 |
| CH₄ | C—H | 3.5 | 12.6 | 0.35 |
| CH₃F | C—H | 4.4 | 13.1 | 0.34 |
| CH₂F₂ | C—H | — | 13.3 | 0.33 |
| CHF₃ | C—H | 6.1 | 14.8 | 0.31 |
| CH₃Cl | C—Cl | 7.5 | 11.3 | 0.31 |
| CH₂Cl₂ | C—Cl | — | 11.3 | 0.28 |
| CHCl₃ | C—Cl | 12.3 | 11.4 | 0.28 |
| CH₂ClF | C—Cl | 7.2 | 11.7 | 0.27 |
| CHF₂Cl | C—Cl | 7.7 | 12.3 | 0.26 |
| CHFCl₂ | C—Cl | 10.7 | 12.4 | 0.26 |
| CH₃Br | C—Br | 8.5 | 10.5 | 0.28 |
| CH₂Br₂ | C—Br | 11.7 | 10.5 | 0.25 |
| CHBr₃ | C—Br | — | 10.7 | 0.22 |
| CH₃CN | C—H | 6.3 | 12.4 | 0.28 |
| CF₃CN | C—F | 6.3 | 14.0 | 0.39 |
| HCN | C—H | — | 13.7 | 0.41 |
| CClF₃ | C—Cl | 8.1 | 13.1 | 0.27 |
| CCl₂F₂ | C—Cl | 11.0 | 11.7 | 0.28 |
| CCl₃F | C—Cl | 13.2 | 11.7 | 0.27 |
| CCl₄ | C—Cl | 16.0 | 11.5 | 0.26 |
| CS₂ | C—S | 8.0 | 10.0 | 0.41 |
| Si₂H₆ | Si—H | 8.1 | 9.9 | 0.31 |
| GeH₄ | Ge—H | 5.3 | 10.5 | 0.32 |
| SiH₄ | Si—H | 5.2 | 11.2 | 0.28 |
| Ge₂H₆ | Ge—Ge | 7.6 | 12.5 | 0.23 |
| C₂H₆ | C—C | 6.4 | 11.6 | 0.33 |
| B₂H₆ | B—H | 11.0 | 11.4 | 0.30 |
| CH₂CF₄ | C—C | — | 13.3 | 0.35 |
| CH₃CF₃ | C—C | — | 13.3 | 0.33 |
| CH₃NH₂ | C—N | — | 9.5 | 0.36 |

TABLE 2
Dopant sources and target ionic species
paired with suitable assistant species

| | Dopant Source | | | |
|---|---|---|---|---|
| | GeF₄ | BF₃ | SiF₄ | CO |
| | Target Ionic Species | | | |
| | Ge | B, BF₂ | Si | C |
| | Assistant Species General Formulas | | | |
| Assistant | CHᵢFⱼCl_{y}Br_{z}I_{q} | CHᵢFⱼCl_{y}Br_{z}I_{q} | | |
| Species | CᵢHⱼN_{y}X_{z} | CᵢHⱼN_{y}X_{z} | CHᵢFⱼCl_{y}Br_{z}I_{q} | |
| Specific | Si_{q}H_{y}X_{z} | Si_{q}H_{y}X_{z} | CᵢHⱼN_{y}X_{z} | Si_{q}H_{y}X_{z} |
| CS₂ | X | X | X | |
| C₂H₆ | X | X | X | |
| CH₃F | X | X | X | |
| CH₃CN | X | X | X | |
| CH₂ClF | X | X | X | |
| CH₃Cl | X | X | X | |
| CF₄ | X | X | X | |
| CH₄ | X | X | X | |
| CH₂F₂ | X | X | X | |
| CHF₃ | X | X | X | |
| CH₂Cl₂ | X | X | X | |
| CHCl₃ | X | X | X | |
| CHF₂Cl | X | X | X | |
| CHFCl₂ | X | X | X | |
| CH₃Br | X | X | X | |
| CH₂Br₂ | X | X | X | |
| CHBr₃ | X | X | X | |
| CF₃CN | X | X | X | |
| HCN | X | X | X | |
| CClF₃ | X | X | X | |
| CCl₂F₂ | X | X | X | |
| CCl₃F | X | X | X | |
| CCl₄ | X | X | X | |
| CH₂CF₄ | X | X | X | |
| CH₃CF₃ | X | X | X | |
| CH₃NH₂ | X | X | X | |
| SiH₄ | X | X | | X |
| Si₂H₆ | X | X | | X |
| SiH₃Cl | X | X | | X |
| SiH₂Cl₂ | X | X | | X |
| Ge₂H₆ | | X | X | X |
| GeH₄ | | X | X | X |
| B₂H₆ | X | | X | X |

1. A method of increasing a beam current for implanting a non-carbon target ionic species, comprising the steps of:
introducing a dopant source into an ion implanter from a delivery container;
introducing an assistant species into the ion implanter from the delivery container, said assistant species comprising:
(i) a lower ionization energy in comparison to an ionization energy of the dopant source;
(ii) a total ionization cross-section (TICS) greater than 2 Å²;
(iii) a ratio of bond dissociation energy (BDE) of a weakest bond of the assistant species to the lower ionization energy of the assistant species to be 0.2 or higher; and
(iv) an absence of the non-carbon target ionic species;
ionizing the assistant species to produce ions of the assistant species;
the dopant source interacting with the assistant species whereby the dopant source undergoes assistant species ion-assisted ionization;
forming a plasma containing ions;
extracting a beam of the ions from the ion implanter;
separating the ions to isolate non-carbon target ionic species;
producing the beam current of the non-carbon target ionic species that is higher in comparison to that generated solely from the dopant source; and
implanting the non-carbon target ionic species into a substrate.

2. The method of claim 1, wherein the dopant source is in a concentration higher than that of the assistant species.

3. The method of claim 1, further comprising introducing a diluent gas into the ion implanter.

4. The method of claim 1, further comprising:
operating at a predetermined arc voltage at which said assistant species has a TICS greater than that of said dopant source.

5. The method of claim 1, wherein the step of the dopant source interacting with the assistant species whereby the dopant source undergoes assistant species ion-assisted ionization further comprises the assistant species diluting the dopant source.

6. The method of claim 1, further comprising the step of manipulating an arc voltage, arc current, flow rate, or extraction voltage of the ion implanter at a level that is suitable for the dopant source to undergo the assistant species ion-assisted ionization.

7. The method of claim 1, wherein the production of the beam current at a power level and a flow rate is 5% or higher in comparison to the beam current generated solely from the dopant source with a diluent at the power level and the flow rate.

8. The method of claim 1, wherein the production of the beam current at a power level and a flow rate is 10% or higher in comparison to the beam current generated solely from the dopant source with a diluent at the power level and the flow rate, and further wherein the TICS of the assistant species is greater than 3 Å².

9. The method of claim 1, further comprising withdrawing the dopant source and the assistant species from the delivery container at a flow rate in a range of 0.1-100 sccm.

10. The method of claim 3, further comprising extracting the ions from ion implanter at an extraction voltage ranging from 500V to 50 kV.

11. The method of claim 1, further comprising operating the ion implanter at an arc voltage ranging from 50-150 V.

12. The method of claim 1, wherein the step of introducing the assistant species and introducing the dopant source comprises flowing the assistant species and flowing the dopant source to achieve a source life of at least 50 hours.

13. The method of claim 1, wherein the beam current is 5% or higher than that generated solely from the dopant source.

14. The method of claim 1, wherein the beam current is 10% or higher than that generated solely from the dopant source.

15. The method of claim 1, wherein the beam current is 20% or higher than that generated solely from the dopant source.

16. The method of claim 1, wherein the beam current is 25% or higher than that generated solely from the dopant source.

17. The method of claim 1, wherein the beam current is 30% or higher than that generated solely from the dopant source.

18. The method of claim 1, wherein the assistant species and dopant source are withdrawn from the delivery container in response to a sub-atmospheric downstream condition.

19. The method of claim 1, wherein the assistant species interacts with the dopant source to enhance formation of the non-carbon target ionic species from the dopant source wherein at least 10¹¹ atoms/cm² of the non-carbon target ionic species from the dopant source is implanted into the substrate.

20. The method of claim 1, wherein the step of introducing the assistant species and the step of introducing the dopant source comprises flowing the assistant species and the dopant source as a mixture wherein a concentration of the assistant species is less than that of the dopant source.

21. The method of claim 1, wherein the assistant species interacts with the dopant source to enhance formation of the non-carbon target ionic species from the dopant source wherein the beam current of the non-carbon target ionic species ranges from 10 microamps to 100 mA.

22. The method of claim 1, further comprising the step of generating the higher beam current that is at least about 1 mA for a source life of at least 50 hours.

23. A method of producing an increased beam current for implanting a non-carbon target ionic species, comprising the steps of:
introducing a dopant source into an ion implanter;
introducing an assistant species into the ion implanter, said assistant species comprising:
(i) a lower ionization energy in comparison to an ionization energy of the dopant source;
(ii) a total ionization cross-section (TICS) greater than 2 Å²;
(iii) a ratio of bond dissociation energy (BDE) of a weakest bond of the assistant species to the lower ionization energy of the assistant species to be 0.2 or higher; and
(iv) an absence of the non-carbon target ionic species;
ionizing the assistant species to produce ions of the assistant species;
the dopant source interacting with the assistant species whereby the dopant source undergoes assistant species ion-assisted ionization;
forming a plasma containing ions;
extracting a beam of the ions from the ion implanter;
separating the ions to isolate non-carbon target ionic species;
producing the increased beam current of the non-carbon target ionic species that is higher in comparison to that generated solely from the dopant source; and
implanting the non-carbon target ionic species into a substrate.

24. The method of claim 23, wherein the dopant source and the assistant species are co-flowed, sequentially flowed or mixed together.

25. The method of claim 23, wherein a first delivery container and a second delivery container are provided as a part of a gas kit, said first delivery container comprising the dopant source, and said second delivery container comprising the assistant species.

26. The method of claim 23, wherein the dopant source and the assistant species are introduced from a single delivery container.
